(19) United States
(12) Patent Application Publication
(10) Pub. No.: US 2026/0117367 A1
(43) Pub. Date: Apr. 30, 2026

(54) Method, control device, computer program and storage medium

(71) Applicant: VON ARDENNE Asset GmbH & Co. KG, Dresden (DE)

(72) Inventor: Bernd Galonska, Dresden (DE)

(21) Appl. No.: 19/150,807

(22) PCT Filed: Jan. 4, 2024
(86) PCT No.: PCT/EP2024/050137

§ 371 Date: Jul. 24, 2025

(30) Foreign Application Priority Data
Jan. 31, 2023 (DE) 10 2023 102 251.2

(51) Int. Cl. C23C 14/54; C23C 14/08; C23C 14/50; C23C 14/56

(52) U.S. Cl. CPC C23C 14/547; C23C 14/083; C23C 14/505; C23C 14/568

(57) ABSTRACT

According to various embodiments, a method can comprise: determining an actual state of a result of a two-sided coating process, by means of which a first layer stack is formed on a front side of a substrate and a second layer stack is formed on a rear side of the substrate, on the basis of: a model, which implements a link between the result and a spectral response of the result, and an actual state of the spectral response, an indication of the difference between a first sub-process of the coating process, by means of which the first layer stack is formed, and a simultaneous second sub-process of the coating process, by means of which the second layer stack is formed, and controlling the coating process on the basis of the actual state of the result.

### FIELD

Various embodiments relate to a method, a computer program, a control device and a storage medium.

### BACKGROUND

In general, a substrate, for example, a glass substrate, a metal substrate and/or a polymer substrate, may be processed, e.g., coated by a coating process, so that the chemical and/or physical (e.g., optical) properties of the substrate may be changed. By the coating process (e.g., by chemical and/or physical vapor deposition), for example, a layer stack may be formed in order to specifically adjust the optical properties of the resultant product, such as its optical spectrum. For example, a vacuum coating system may be used to deposit one or more than one stack of several layers (also referred to as a layer stack) by the coating process, whose optical interaction with each other is intended to meet requirements for a reflection or transmission characteristic or a color impression. One such application is the coating of optical components such as lenses, prisms or mirrors.

In general, such a coating process may be controlled, for example, by an optical measurement that is carried out at regular intervals on the time-dependent actual state of the result of the coating process. However, the complexity of such control increases considerably with the number of interacting layers, so that computer-implemented models are used to monitor the progress of the coating process based on the optical measurement (also known as monitoring).

According to various embodiments, it has been recognized that the possibilities for monitoring the coating process are limited in various applications, including when the substrate is to be coated on both sides, for example, with layer stacks of similar structure, preferably simultaneously, and/or made of transparent material. In particular, a reflection measurement as an optical measurement is more difficult with a layer stack made of transparent material, as the optical measurement captures both layer stacks, which is also the case with a transmission measurement, for example,. Illustratively, the greater the similarities between the layer stacks, the greater the risk that they will be difficult to distinguish from each other using the optical measurement, so that the coating process is controlled on an imprecise basis and, as a result, high demands on the result may only rarely be met. For example, the layer thicknesses determined by optical measurement may no longer be uniquely assigned to the respective stack, which makes reliable control impossible.

In this context, it was illustratively recognized that this risk may be reduced if, in addition (to the optical measurement), one or more than one difference between the layer stacks is taken into account. This consideration illustratively improves the data basis (e.g., through additional boundary conditions) for the control. However, there is a particular challenge in the case that these layer stacks have a uniform target structure, are both recorded by the optical measurement and are to be formed simultaneously (e.g., with a temporal overlap). In this case, it was recognized that a usable difference between the layer stacks may be generated by the fact that their actual state differs from each other at the time or at each point in time at which the optical measurement takes place. This may be achieved, for example, by forming the two layer stacks at different speeds or at different times. Such a procedure maximizes the temporal overlap of the formation of the two layer stacks, so that the coating of the substrate takes less time overall and is therefore more cost-effective.

### SUMMARY

According to various embodiments, a method, a computer program, a control device and a storage medium are provided which enable one or more than one of the following:
that the substrate may be coated on both sides at the same time, if possible, which increases the throughput of the coating process and thus its cost-effectiveness without having to retool it;
that high demands on the result are not only achieved when the layer stacks are deposited one after the other;
the fact that a high calibration effort is avoided is illustrative, as higher fluctuations in the sub-processes that occur in reality anyway may be accepted in order to stimulate this difference; and,
that additional sensor technology is not necessarily required (e.g., for reflectance measurement) in order to improve the data basis.

### BRIEF DESCRIPTION OF THE DRAWINGS

In the figures:

FIG. 1 shows a processing arrangement according to various embodiments in a schematic side view or cross-sectional view;

FIG. 2A and B respectively show the processing arrangement according to different embodiments in a schematic side view or cross-sectional view;

FIG. 3A and B respectively show the result of the coating process according to different embodiments in a schematic side view or cross-sectional view;

FIG. 4A and B respectively show a spectral response according to different embodiments in a schematic diagram;

FIG. 5A to C respectively shows a spectral response according to different embodiments in a schematic diagram;

FIG. 6A and B respectively show the coating process according to different embodiments in different schematic diagrams; and,

FIG. 7 shows a vacuum arrangement according to various embodiments in a schematic top view or cross-sectional view.

### DETAILED DESCRIPTION OF THE INVENTION

In the following detailed description, reference is made to the accompanying drawings which form part thereof and in which specific embodiments in which the invention may be practiced are shown for illustrative purposes. In this regard, directional terminology such as “top”, “bottom”, “front”, “rear”, “front”, “rear”, etc. is used with reference to the orientation of the figure(s) described. Since components of embodiments may be positioned in a number of different orientations, the directional terminology is for illustrative purposes and is not limiting in any way. It is understood that other embodiments may be used, and structural or logical changes may be made without departing from the scope of protection of the present invention. It is to be understood that the features of the various exemplary embodiments described herein may be combined with each other, unless specifically indicated otherwise. The following detailed description is therefore not to be construed in a limiting sense, and the scope of protection of the present invention is defined by the appended claims.

In the context of this description, the terms “connected”, “connected” and “coupled” are used to describe both a direct and an indirect connection (e.g., ohmic and/or electrically conductive, e.g., an electrically conductive connection), a direct or indirect connection and a direct or indirect coupling. In the figures, identical or similar elements are provided with identical reference signs where this is appropriate.

The actual state of an entity (e.g., a device, a system or an operation, i.e., a process) may be understood as the actual or sensorily measurable state of the entity. The desired state of the entity, i.e., a specification, may be understood as the target state of the entity. Control may be understood as an intended influence on the current state (also referred to as the actual state) of the entity. The current state may be changed according to the specification (also referred to as the target state), e.g., by changing one or more than one operating parameter (then also referred to as a manipulated variable) of the entity, e.g., by a manipulation member. Regulation may be understood as control, wherein a change of state is also counteracted by disturbances. For this purpose, the actual state is compared with the target state and the entity is influenced, e.g., by a manipulation member, in such a way that the deviation of the actual state from the target state is minimized. In contrast to pure forward sequential control, closed-loop control thus implements a continuous influence of the output variable on the input variable, which is brought about by the so-called control loop (also referred to as feedback). In other words, this may be understood to mean that closed-loop control may be used as an alternative or in addition to open-loop control (or open-loop controlling) or that closed-loop control may be used as an alternative or in addition to closed-loop control.

The state of a controllable device (e.g., a coating device) or a controllable process (e.g., the coating process) may be specified as a point (also referred to as operating point or operating point) in a space (also referred to as state space) that is spanned by the variable parameters of the device or process (also referred to as operating parameters). The state of the device or process is therefore a function of the respective value of one or more than one operating parameter, which thus represents the state of the device or process. The actual state may be determined based on a measurement (e.g., by a sensing member) of one or more than one operating parameter (then also referred to as a controlled variable). Examples of an operating parameter of a process (e.g., the coating process or a sub-process thereof) include: a time at which the process is started or continued; a time at which the process is interrupted or terminated; a period for which the process is interrupted or carried out; a speed at which the process is carried out; a temperature to which the process is exposed; a pressure to which the process is exposed. For example, the speed may be expressed as a rate (change per time), e.g., as a coating rate (e.g., expressed as an increase in coating thickness on the substrate per time) and/or as an emission rate (e.g., measured as an increase in coating thickness on a rate sensor per time). In relation to a sputtering device, the emission rate is also referred to as the atomization rate.

The state of the system may thus represent the state of each coating process of the system and vice versa. The actual state of each process (e.g., the coating process or each sub-process thereof) may be sensed by a sensing member (e.g., comprising one or more than one sensor). One or more than one sensor may be used per controlled variable, which is configured to sense a variable (also referred to as measurement variable) which represents the controlled variable or which is the controlled variable.

A sensor (also referred to as a detector) may be understood as a transducer that is configured to sense a property of its environment (e.g., qualitative or quantitative) corresponding to the sensor type as a measurement variable, e.g., a physical property, a chemical property and/or a material property. The measurand is the physical quantity (also referred to as the controlled variable) to which the measurement by the sensor applies. Depending on the complexity of the environment to be measured by the sensor, the sensor may be configured to distinguish between two or more discrete states of the measurement variable (also referred to as a measuring switch) or to sense the measurement variable quantitatively. An example of a sensed measurement variable is, for example, a gas inflow rate (e.g., sensed as a flow rate), the actual state of which may be converted into a measured value using the sensor.

Each sensor may be part of a measuring chain which has a corresponding infrastructure (e.g., processor, storage medium and/or bus system and the like). The measuring chain may be configured to control the corresponding sensor, process its recorded measurement variable as an input variable and based on this, provide an electrical signal as an output variable that represents the recorded input variable. For example, the output variable may indicate the measured value. The measurement chain may be or be implemented by a so-called control device, for example.

In the following, exemplary reference is made, inter alia, to reactive processes in which a chemical reaction takes place. For example, one or more than one process (e.g., coating process or sub-process thereof) may comprise a reactive sputtering process which is provided with one or more than one reactive gas (e.g., a number of m reactive gases) which forms a chemical bond with the coating material (also referred to as target material) which is deposited (then also referred to as layer forming material) on a substrate (where, for example, m=1, m>1 or m>2). It may be understood that the coating process does not necessarily have to be reactive. The quantities that represent materials involved in the chemical reaction in a reactive coating process may represent corresponding other materials that are not involved in a chemical reaction in a non-reactive coating process. Accordingly, what is described for the reactive coating process may apply by analogy to a non-reactive coating process and vice versa.

According to various embodiments, reference is made to physical vapor deposition (PVD) as an exemplary coating process, e.g., comprising a sputtering process. It may be understood that what is described for PVD may apply by analogy to chemical vapor deposition (CVD). In contrast to CVD, in PVD a solid material is first converted into the gas phase (also known as the gaseous phase or vapor) and a layer is formed by this gas phase. In PVD, the gas phase of the target material may optionally be chemically reacted with a reactive gas to form a chemical compound, which is incorporated into the layer or forms it. In the chemical reaction of PVD, two or more materials are thus combined to form the chemical compound.

In chemical vapor deposition, a gaseous starting compound (also referred to as precursor or reactant) is split into at least two reaction products, of which at least one reaction product is incorporated into the coating and optionally one reaction product is removed from the coating process as an excess (e.g., by a pump). Optionally, CVD may be carried out by a plasma in which the precursor is split.

A plasma may be formed by a so-called working gas (also known as a plasma-forming gas). According to various embodiments, the working gas may comprise a gaseous material which is inert, in other words, which participates in few or no chemical reactions. For example, a working gas may be or be defined by the target material used and be or be adapted to it. For example, a working gas may be a gas or a gas mixture that does not react with the target material to form a solid. The working gas can, for example, contain a noble gas (e.g., helium, neon, argon, krypton, xenon, radon) or several noble gases. The plasma may be formed from the working gas, which essentially atomizes the target material, for example. If a reactive gas is used, this may have a higher chemical reactivity than the working gas, e.g., with regard to the target material. In other words, the atomized target material together with the reactive gas (if present) may react faster (i.e., form more reaction product per time) than together with the working gas (e.g., if it chemically reacts with the working gas at all). The reactive gas and the working gas may be supplied together or separately as a process gas (e.g., as a gas mixture), for example, by the gas supply device.

The reactive gas may comprise a gaseous material that reacts with the target material (e.g., with the atomized target material) and/or may be incorporated into the deposited layer by a chemical reaction. If, for example, a target material is used which may form a nitride (e.g., aluminum nitride), or if a nitride of the target material is to be deposited, the reactive gas may contain nitrogen or be formed from nitrogen. If, for example, a target material is used which may form an oxide (e.g., aluminum oxide), or if an oxide of the target material is to be deposited, the reactive gas may comprise oxygen or be formed from it. The reactive gas may, for example, comprise or be formed from a gas mixture (reactive gas mixture) of several gases which react with the target material and/or the deposited layer, e.g., oxygen and nitrogen, e.g., if an oxynitride (e.g., aluminum oxynitride) is to be deposited. The reactive gas mixture may, for example, comprise predominantly (i.e., more than 50%) oxygen, e.g., for depositing an oxide or oxynitride. Examples of reactive gas include: molecular oxygen, molecular nitrogen, nitrogen oxide, carbon oxide, hydrogen sulfide, methane, gaseous hydrocarbon, molecular fluorine, molecular chlorine, ozone, or another gaseous material.

In an exemplary implementation, the can, for example, have a vacuum-assisted coating (e.g., the formation of the individual layers of the layer stack) with the aid of an electrical discharge (also referred to as plasma). For this purpose, a plasma-forming (e.g., inert) gas may be ionized by a cathode, wherein a material to be deposited (also referred to as a target) may be atomized (also referred to as sputtering) by the plasma formed in the process. The atomized material may then be brought to a substrate on which it may be deposited and form a layer (also known as a coating). Modifications of cathode sputtering are sputtering using a magnetron, known as magnetron sputtering, e.g., reactive magnetron sputtering or non-reactive magnetron sputtering. The formation of the plasma may be supported by a magnetic field, which may influence the ionization rate of the plasma-forming gas. The magnetic field may be generated by a magnet system, wherein a plasma channel may be formed by the magnetic field, in which the plasma may form. For sputtering, the coating material may be arranged as a solid body (also referred to as a target) between the plasma channel and the magnetic system so that the target may be penetrated by the magnetic field and the plasma channel may form on the target. The plasma-forming gas (e.g., argon) together with an optional reactive gas may form a process gas in which sputtering takes place. The reactive gas may be used for reactive magnetron sputtering.

In the following, reference is made to a method which has the control of a coating process, which may be carried out, for example, by controlling one or more than one manipulation member (also referred to as positioning). In this context, reference is also made to a control device or code segments. The control device (also referred to as a control device) may be configured to implement one or more than one of the methods described herein. For this purpose, the control device may have a processor that is configured to implement the respective method. For example, the processor may be configured to issue corresponding instructions for controlling. Alternatively, or additionally, the processor may be configured to receive and process corresponding instructions and signals. The instructions received by the processor can, for example, be implemented by code segments that are stored in a non-transitory data memory. For example, the code segments may comprise at least instructions and/or one or more than one instruction which, when executed by the processor, cause the processor to perform one of the methods.

The term “control device” may be understood as any type of logic-implementing entity that can, for example, have a processor (and, for example, corresponding circuitry) that can, for example, execute software that is stored in a storage medium, in firmware or in a combination thereof, and may issue instructions based thereon. The control device can, for example, be configured by code segments (e.g., software). The control device may, for example, comprise or be formed from a programmable logic controller (PLC).

According to various embodiments, a data storage device (more generally also referred to as a storage medium) may be a non-transitory data storage device. For example, the data memory may comprise or be formed from a hard disk and/or at least one semiconductor memory (such as read-only memory, random access memory and/or flash memory). The read-only memory may, for example, be an erasable programmable read-only memory (may also be referred to as an EPROM). The random access memory may be a non-volatile random access memory (may also be referred to as NVRAM-“non-volatile random access memory”). For example, the data memory may store one or more than one of the following: the code segments implementing the method, a model or at least parameters thereof, one or more than one indication of a difference between two sub-processes of the coating process.

The term “processor” may be understood as any type of entity that allows the processing of data or signals. For example, the data or signals may be handled according to at least one (i.e., one or more than one) specific function performed by the processor. A processor may comprise or be formed from an analog circuit, a digital circuit, a mixed signal circuit, a logic circuit, a microprocessor, a central processing unit (CPU), a graphics processing unit (GPU), a digital signal processor (DSP), a programmable gate array (FPGA), an integrated circuit, or any combination thereof. Any other type of implementation of the respective functions, which are described in more detail below, may also be understood as a processor or logic circuit, for example, also virtual processors (or a virtual machine) or a plurality of decentralized processors, which are, for example, interconnected by a network, are distributed spatially in any desired manner and/or have any desired shares in the implementation of the respective functions (e.g., computing load distribution among the processors). The same generally applies to a differently implemented logic for implementing the respective functions. It will be understood that one or more of the method steps described in detail herein may be performed (e.g., realized) by a processor, through one or more specific functions performed by the processor.

The term “manipulation member” (e.g., including an actuator) may be understood as a transducer that is configured to influence a state, a process (e.g., a coating process) or a device in response to a control of the manipulation member. The manipulation member may convert a control signal supplied to it (by which the controlling takes place) into mechanical movements or changes in physical variables such as pressure or temperature. An electromechanical manipulation member can, for example, be configured to convert electrical energy into mechanical energy (e.g., through movement) in response to the controlling.

A manipulation member may be configured to influence the actual state (also known as the operating point) of the process (e.g., its manipulated variable), which is supplied by the manipulation member. The influence may be direct or indirect. For example, the manipulated variable and controlled variable may differ from each other. The controlled variable (e.g., pressure) may then be a function of one or more than one manipulated variable (e.g., gas flow).

For example, the manipulation member may change an electrical voltage as a manipulated variable, by which a plasma is supplied, so that as a result a coating rate, an atomization rate or a layer thickness is changed as a controlled variable. For example, the manipulation member may change an inflow rate of a gas as a manipulated variable so that a pressure is changed as a controlled variable as a result. For example, the manipulation member may change an inflow rate of a working gas as a manipulated variable so that an atomization rate or a layer thickness is changed as a controlled variable as a result. For example, the manipulation member may change an inflow rate of a reactive gas as a manipulated variable, so that a chemical composition of the plasma or a coating is changed as a controlled variable as a result.

With regard to the control of a manipulation member, reference is made, among other things, to the more easily understandable control variable or its control value, which is influenced by the manipulation member. What is described for this may apply by analogy to the control variable or its control value, which are fed to the manipulation member for controlling, and vice versa. In other words, the manipulation member acts as a converter that converts a control signal into the control variable or its control value, so that the control value is a function of the control value.

According to various embodiments, the control and/or regulation provided may be used to stabilize the optical product properties (color, transmission, reflection), e.g., by adjusting the layer thicknesses.

According to various embodiments, one or each substrate may comprise or be formed from a foil and/or a glass plate.

For example, one of the layer stacks may comprise or be formed from an optical anti-reflective multilayer system. The anti-reflective multilayer system may comprise: a plurality of transparent and/or dielectric materials which differ from each other in their refractive index; a stack of a plurality of multilayer groups which optionally differ from each other in a total layer thickness, and of which each multilayer group comprises a plurality of layers, of which a first layer comprises or consists of a first material of the plurality of materials, and a second layer comprises or consists of a second material of the plurality of materials.

For example, a layer stack may comprise or be formed from an optical low emission multilayer system. The low emission multilayer system may comprise: a dielectric base layer assembly (e.g., comprising one or more layers) and a dielectric cap layer assembly (e.g., comprising one or more layers); a functional layer assembly (e.g., comprising one or more layers) comprising a metallic functional layer and arranged between the base layer assembly and the cap layer assembly, wherein the cap layer assembly optionally comprises at least one protective layer. The protective layer may, for example, comprise a semi-metal (e.g., silicon) and/or a non-metal (e.g., nitrogen), a nitride thereof and/or an oxide thereof. In some embodiments, the metallic functional layer may be omitted.

According to various embodiments, an object (e.g., the substrate, a material, the layer stack and/or any layer thereof) may be translucent. In the context of this description, the term “translucent” (e.g., transparent or at least translucent) may be understood to mean that the object (e.g., a substrate or a layer or a material) has a transmittance such that a majority of the electromagnetic radiation (e.g., light) striking it passes through it, e.g., more than is absorbed and/or reflected by it. A translucent object can, for example, be translucent (partially translucent). In other words, the degree of transmission within the transmission area may be greater (e.g., at least twice, three times, five times or ten times as great) than the degree of reflection and/or the degree of absorption, e.g., the sum of these.

The transmission coefficient (also referred to as transmittance) may denote the proportion of electromagnetic radiation (e.g., visible light) that passes through the object (e.g., the substrate). The reflectance (also referred to as the reflection coefficient) may denote the proportion of the incident electromagnetic radiation that is reflected (e.g., re-emitted) by the object. The reflectance may take into account directionally reflected radiation (reflected back), diffusely reflected radiation and/or re-emitted radiation. The degree of absorption (also known as the absorption coefficient) may denote the proportion of the incident electromagnetic radiation that is absorbed (i.e., taken up and/or swallowed) by the object, e.g., by converting it into heat.

A transparent object (e.g., the substrate, a material, the layer stack and/or any layer thereof) may have a transmittance (transmission coefficient) that is greater than about 50%, e.g., greater than about 60%, e.g., greater than about 70%, e.g., greater than about 80%, e.g., greater than about 90%. For example, the transmittance may be in a range of approximately 70 % and approximately 99 %.

In general, the transmittance may depend on the wavelength of the electromagnetic radiation according to the optical properties of the object. For example, the layer stack may be transparent for one or more wavelength ranges while being opaque for one or more additional wavelength ranges, i.e., filtering them out. The one or more wavelength ranges filtered out may be absorbed and/or reflected.

According to various embodiments, such information on optical properties (e.g., transmittance, reflectance and/or absorptance) may be related to a certain wavelength range (also referred to as the transmission range) of the electromagnetic radiation, e.g., that of the visible light (i.e., a wavelength range from about 380 nm to about 780 nm) or to a cut-off wavelength or to 550 nm.

According to various embodiments, a dielectric object (e.g., material or structure, e.g., layer) may be understood to be electrically insulating, e.g., having an electrical conductivity of less than 10-6 Siemens/meter. The dielectric object may, for example, comprise or be formed from an oxide and/or nitride ceramic (e.g., as a compound of a metal). Oxidic may be understood to mean that the object comprises or may be formed from an oxygen compound (e.g., a metal oxide). Nitridic may be understood to mean that the object comprises or may be formed from a nitrogen compound (e.g., a metal nitride). The dielectric object may, for example, be transparent.

For the purposes of this description, a metal (also referred to as a metallic material) may comprise (or be formed from) at least one metallic element (i.e., one or more metallic elements), e.g., at least one element from the following group of elements: Copper (Cu), Iron (Fe), Titanium (Ti), Nickel (Ni), Silver (Ag), Chromium (Cr), Platinum (Pt), Gold (Au), Magnesium (Mg), Aluminum (Al), Zirconium (Zr), Tantalum (Ta), Molybdenum (Mo), Tungsten (W), Vanadium (V), Barium (Ba), Indium (In), Calcium (Ca), Hafnium (Hf) and/or Samarium (Sm).

In order to carry out a two-sided coating, in which the formation of the individual layers is controlled by an optical monitoring system, it may be conventionally necessary to deposit the individual layers (also referred to as individual layers) one after the other, as the layer thicknesses of the individual layers cannot be uniquely determined, particularly if the layer stacks formed on the front and back are identical. Simultaneous coating is then only possible in a time-controlled manner or by determining the rate by using oscillating crystals as a rate sensor. This is not sufficient for the requirements of precision optics.

According to various embodiments, it is possible to achieve almost simultaneous coating of both sides independently (also referred to as two-sided coating) of the coating system, controlled by optical monitoring. Simultaneous coating may be understood to mean that the proportion of the total period of the coating process for which the substrate is coated on one side only is smaller than the proportion of the total period of the coating process (or 50% thereof or 25% thereof or 10% thereof) for which the substrate is coated on both sides. The total period of a two-sided coating process is thus smaller than when the same result is formed by one-sided coating.

By skillfully selecting the working parameters of the coating process (also referred to as coating parameters), e.g., the start time of the coating process or sub-process thereof, sufficient information is provided to determine the layer thicknesses and coating rates in-situ (e.g., without interrupting the vacuum) from an optical spectrum, even if the same layer system (e.g., transparent layers) is deposited on the front and back. This is discussed in more detail below.

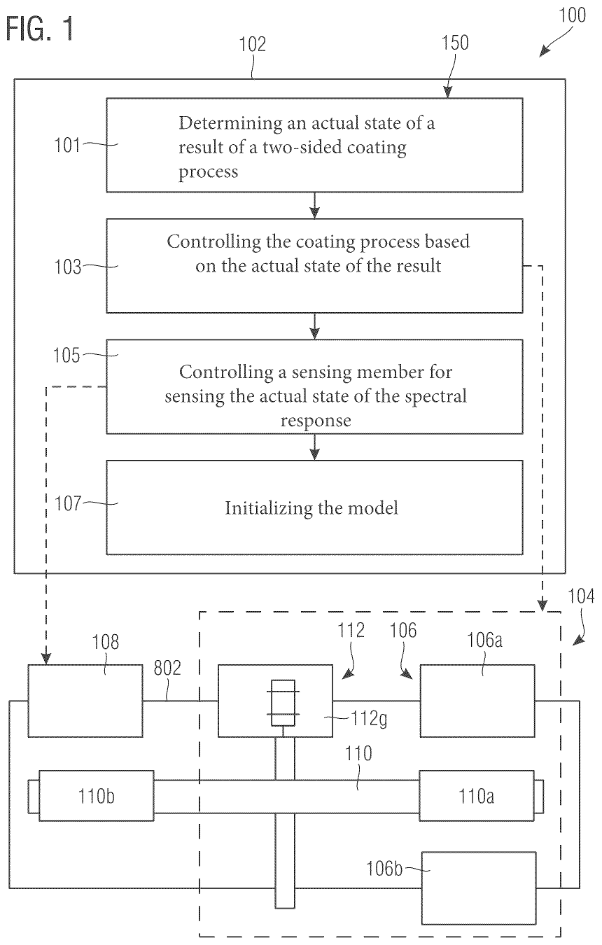

FIG. 1 illustrates a processing arrangement 100 according to various embodiments in a schematic side view or cross-sectional view, which comprises a control device 102 and a vacuum arrangement 104.

The control device 102 may include at least one (e.g., one or more than one) processor configured to perform the method 150. For example, the control device 102 may be arranged to execute code segments (e.g., implementing instructions) that cause the processor to perform the method 150. For example, the code segments may be stored locally by a computer readable medium of the control device 102, or at least partially, provided by a cloud. In this regard, it may be understood that what is described for the control device 102 may apply by analogy to computerized implementations of the method of other types that do not necessarily require, for example, a control device 102 and/or a computer readable medium.

The vacuum assembly 104 may include: a vacuum chamber 802, a transport device 112 for transporting a substrate along a transport path in the vacuum chamber 802, a coating device 106 for performing a coating process adapted to coat the substrate on two sides (also referred to as a two-sided coating process), and a measuring member 108.

An exemplary implementation of the transport device 112 has a substrate carrier 110 (also referred to as carrier) arranged in the vacuum chamber 802 and an manipulation member 112g which is arranged to be controlled in response to apply a mechanical force to the substrate carrier 110, by which the substrate carrier 110 may be moved (e.g., rotated).

An exemplary implementation of the substrate support 110 has one or more than one (e.g., plate-shaped) support having one or more than one substrate support region 110a, 110b, each substrate support region being penetrated by a through opening and having a support surface extending into the through opening on which a substrate may rest.

An alternative exemplary implementation of the substrate carrier 110 is rotatably mounted so that the transport path runs along a curved path (e.g., a closed path). For example, the substrate carrier 110 may perform several rotations during the coating process, e.g., per layer of the layer stack, or alternatively, several oscillating movements.

The method comprises, in 101, determining an actual state of a result of the two-sided coating process (also referred to as a coating result), and in 103, driving the coating process and based on the actual state of the coating result, optionally in 105, driving a measuring member 108 for sensing an actual state of a spectral response of the coating result, and optionally in 107, initializing the model (for example, based on the process difference).

The coating process may be arranged to form two layer stacks (also referred to as coatings), of which a first layer stack is formed on a first side of the substrate by a first sub-process and a second layer stack is formed on a second side of the substrate opposite the first side by a second sub-process. For ease of differentiation between the two sides of the substrate and corresponding terms, reference is made in this regard to “front side” and “back side”, it being understood that this is merely exemplary (for example, not intended to indicate a preference) and may apply interchangeably by analogy.

The target state of the coating result (e.g., the result at the end of the coating process) comprises: the substrate 250, the first layer stack 302 (also referred to as the front side coating) on the front side of the substrate 250, and the second layer stack 304 (also referred to as the back side coating) on the back side of the substrate 250. It may be understood that the actual state of the coating result may differ from the target state of the coating result, for example, in one or more than one layer (e.g., per layer stack).

Reference is made herein and in particular hereinafter, inter alia, to the description of a single layer stack for simplified understanding, wherein it may then be understood that what is described for this may apply by analogy to each of the two layer stacks, for example, if these are to satisfy an identical specification, but need not necessarily do so. Examples of a specification which at least one (one or each) of the two layer stacks may satisfy include: the spatial sequence of layers of different chemical composition; a chemical composition of one or more than one layer; a number of layers of different chemical composition; a total thickness; the spectral response.

The coating device 106 has, for example, per layer stack of the two layer stacks, at least one (one or more than one) coating material source 106a, 106b, which is configured to perform the sub-process for forming the layer stack. The transport path may be arranged between two coating material sources 106a, 106b. The at least one coating material source 106a, 106b may have, for example, one coating material source per layer of the layer stack. Reference is made herein by way of example to two coating material sources per layer stack, i.e., two first coating material sources for forming the front side coating and two second coating material sources for forming the back side coating. It may be understood that what is described herein may apply by analogy to any different number of coating material sources per layer stack. In general, the number of coating material sources per layer stack may depend on how many layers of different properties are to be formed per layer stack.

An exemplary implementation of the at least one coating material source 106a, 106b has, for example, a sputtering device (and optionally an ion source) as the coating material source 106a, 106b for each layer of the layer stack.

An exemplary implementation of the sensing member is configured to sense a transmission spectrum as a spectral response. For this purpose, the sensing member has a source of optical radiation (e.g., a light source) and one or more than one sensor, between which the transport path runs. It may be understood herein that what is described for the transmission spectrum may apply by analogy to spectra of other types, for example, a reflectance spectrum and/or a spectrum determined by ellipsometry (i.e., by an ellipsometer).

The determination 101 of the actual state may be based on a model that implements a correlation between the coating result (e.g., its state, e.g., its target state or actual state) and a spectral response (e.g., an estimate thereof) of the result. For example, the model may have an algorithm by which the state of the coating result and the spectral response may be mapped to each other. Implementations of this may be found, for example, in so-called design software for optical coatings, such as the “OptiLayer” software from OptiLayer GmbH (as of January 2023). This offers, for example, the possibility of simulating the spectral response of a layer stack based on a model of the layer stack, which takes into account the individual layers, their sequence, thickness and optical density. Alternative or additional implementations are explained in DE 10 2018 101 173 and DE 10 2020 124 934.

The determination 101 of the actual state may further be based on an indication of a difference (also referred to as process difference) between the first sub-process of the coating process (also referred to as front side process), by which the front side coating is formed, and a simultaneously occurring second sub-process of the coating process (also referred to as back side process), by which the back side coating is formed. The process difference will be discussed in more detail later.

In an exemplary implementation, the method 150 comprises: determining 101 an actual state of a structure of a multilayer system (as a result of the coating process) comprising a substrate, a first layer stack on a front side of the substrate, and a second layer stack on a back side of the substrate, based on: a model that implements a correlation between the structure of the multilayer system and a spectral response (e.g., transmission spectrum) of the multilayer system, the sensor-sensed actual state of the spectral response, and an indication representing a difference in a working state of the spectral response. transmission spectrum) of the multilayer system, the sensed actual state of the spectral response, and an indication representing a difference in an operating point between a first sub-process of the coating process by which the first layer stack is formed and a concurrent second sub-process of the coating process by which the second layer stack is formed (with which they are initiated, for example); and controlling 105 the first sub-process and/or the second sub-process based on the actual state of the multilayer system.

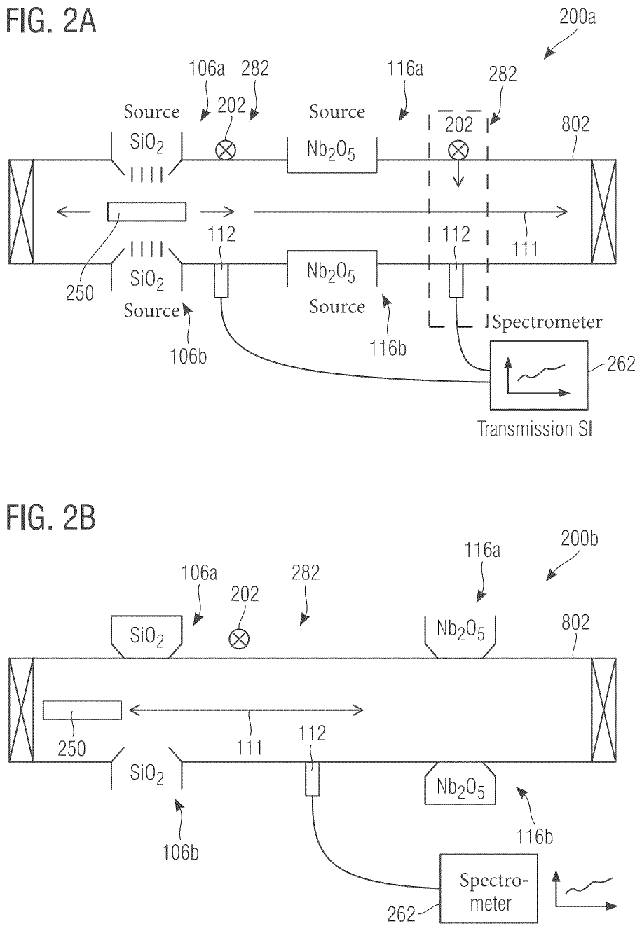

FIGS. 2A and 2B each illustrates the processing arrangement 100 according to various embodiments 200a, 200b in a schematic side view or cross-sectional view, in which the substrate 250 and the transport path 111 are shown. Furthermore, an exemplary implementation of the coating device 106 is shown, in which it comprises two first coating material sources 106a, 116a for forming the front side coating and two second coating material sources 106b, 116b for forming the back side coating. A coating material source 106a, 106b configured as a silica oxide source and a coating material source 116a, 116b configured as a niobium oxide source are arranged above and below the transport path 111.

In the context of a dielectric coating material (e.g., an oxide, a nitride and/or an oxynitride), it may be understood that the coating material source may be arranged to provide a dielectric coating material as a layer forming material, or may also be arranged to emit a metallic coating material which is subsequently converted into the dielectric layer forming material (e.g., by a chemical reaction), for example, after the metallic coating material has been deposited on the substrate.

Further, the transport path 111 may extend through one or more than one measurement area 282 of the processing arrangement, each measurement area comprising a light source 202 and a sensor 212 of the measurement member 108.

Also shown is a spectrometer 262 as an exemplary part of the measurement chain, for example, implemented by the control device.

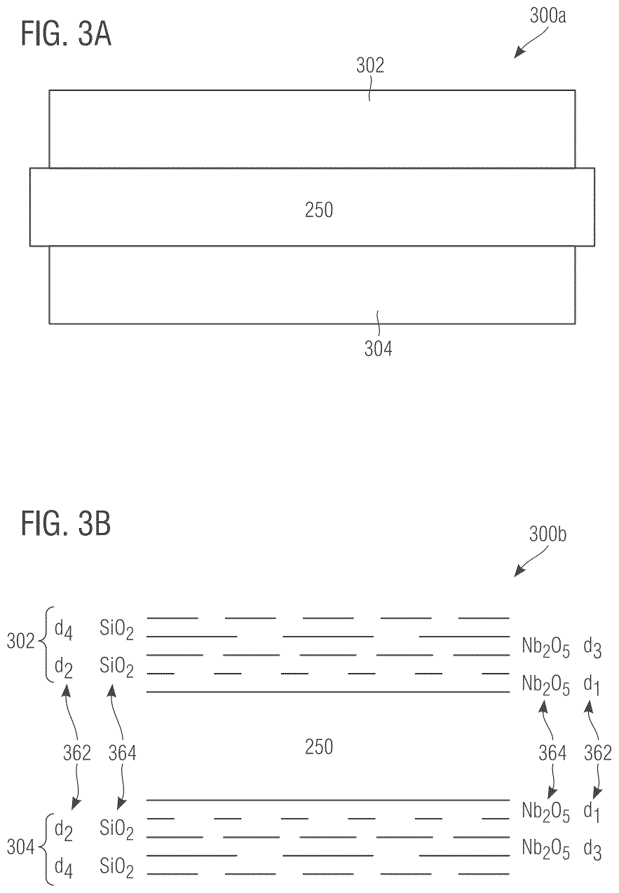

FIGS. 3A and 3B each illustrates the result of the coating process (also referred to as the coating result) according to various embodiments 300a, 300b in a schematic side view or cross-sectional view.

Each of the two-layer stacks 302, 304 between which the substrate 250 is disposed may comprise a plurality of layers, adjacent layers of which differ from each other in one or more of the following: their layer thickness, their chemical composition and/or their optical refractive index. Alternatively, or additionally, adjacent layers of the plurality of layers may differ in that they are optically transmissive (e.g., transparent or translucent) and/or dielectric (i.e., made of a material having this property).

According to embodiments 300b, each of the layer stacks comprises one or more than one multilayer group (e.g., a stack thereof), each multilayer group comprising a first layer and an adjacent second layer disposed between the first layer and the substrate 250, which differ from each other in one or more than one of the following: their layer thickness 362 (herein referred to as d1, d2, . . . , d4), their chemical composition 364, and/or their optical refractive index.

As an exemplary embodiment, the first layer comprises silicon oxide and the second layer comprises niobium oxide, both of which are optically transparent and dielectric. However, it may be understood that the first layer and the second layer may each comprise any suitable material to meet the optical property requirement.

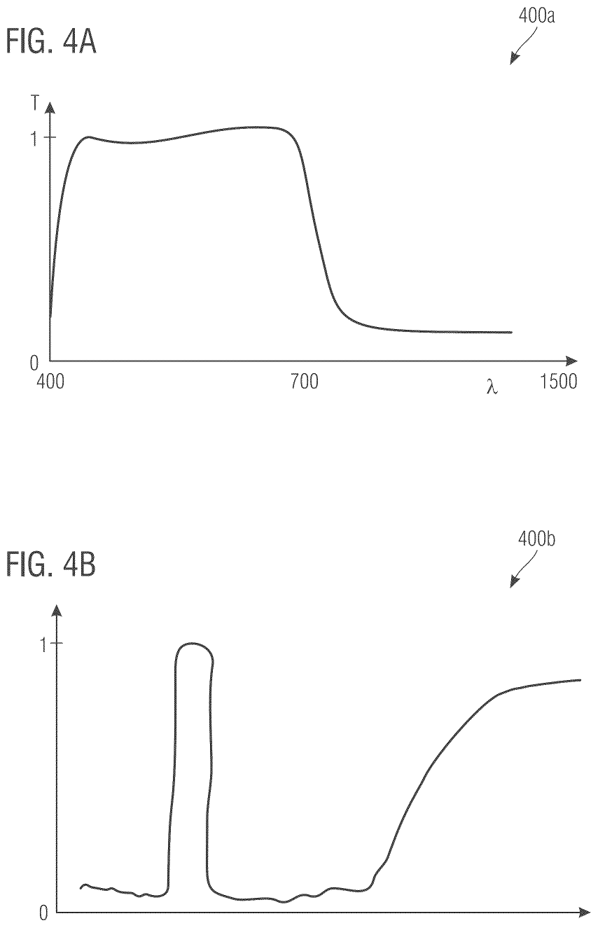

FIGS. 4A and 4B each illustrates different spectral responses according to different embodiments 400a, 400b in a schematic diagram in which the transmission coefficient T over the wavelength 2 (in nanometers) is shown. The spectral responses shown can, for example, be determined as an actual state by sensory means (i.e., by a sensor) or as a target state by the model, for example, if these are to serve in the form of the target state as a specification for the optical properties of the coating result.

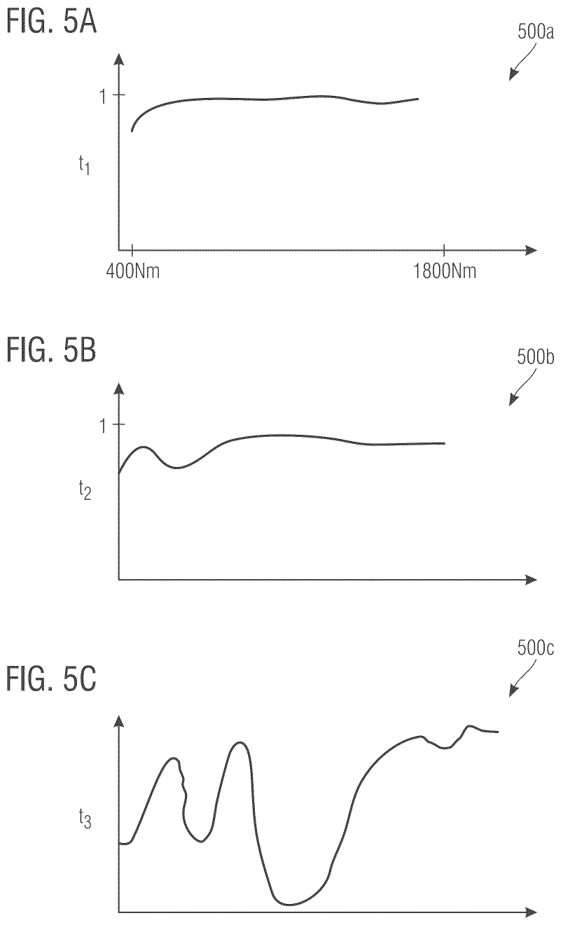

FIGS. 5A and 5B each illustrates a spectral response according to different embodiments 500a, 500b, 500c in a schematic diagram for different actual states of the coating result, shown here at the times t1, t2 and t3 over the course of the coating process. The spectral responses shown can, for example, be recorded by sensors (i.e., by a sensor) as the actual state, for example, as the temporal development of the spectral response during the build-up of a layer stack, or determined as the target state by the model, for example, if these are to serve as a specification for the optical properties of the coating result in the form of the target state.

The spectral response according to embodiments 500a corresponds substantially to that of the substrate, which may be the case when the coating process has just started. The spectral response according to embodiments 500b corresponds to that of a partially completed coating stack. The spectral response according to embodiments 500c corresponds to the completed layer stack.

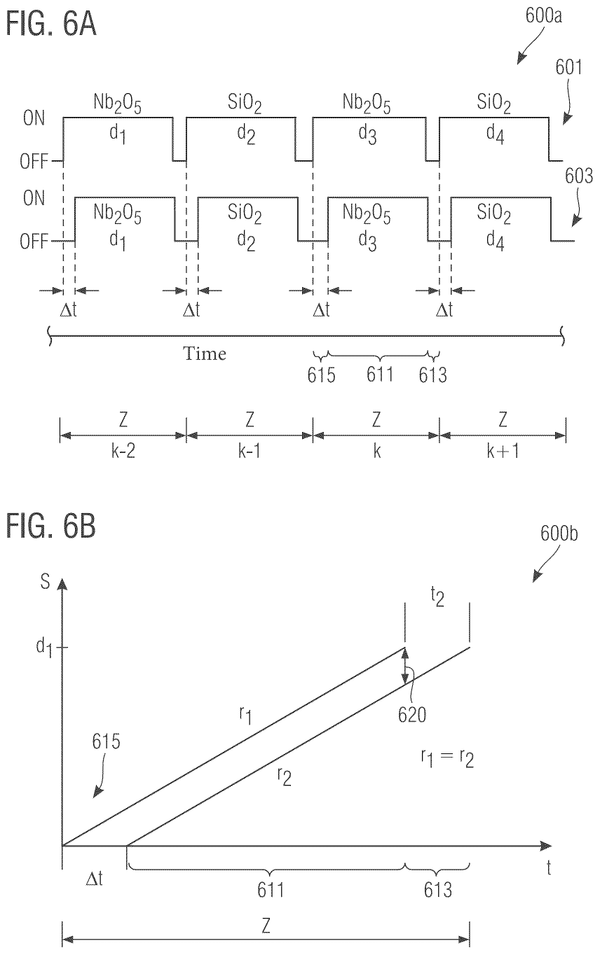

FIGS. 6A and 6B illustrate the coating process according to various embodiments in various schematic diagrams 600a, 600b, in which the coating process is shown over time t, and a comparison of the front side process 601 to the back side process 603 is shown. The coating process may be performed according to a cycle Z that includes a first phase 615 (also referred to as a start phase), a second phase 611 (also referred to as a two-side coating phase), and a third phase 613 (also referred to as a finish phase), for example, in which the substrate is transported (e.g., uninterruptedly).

Each cycle is associated with a layer of the layer stack, which is formed in the cycle by the front side process 601 and the back side process 603 from a layer forming material. For example, the layer forming material is provided at the transport path and/or in a coating area through which the substrate is moved along the transport path (e.g., by a pendulum movement or rotary movement of the substrate carrier). In general, immediately successive cycles may differ from each other in the layer forming material by which the layer of the layer stack assigned to them is formed.

In the following, reference is made to a k-th (1≤k, e.g., 2≤k, e.g., 3≤k) cycle, wherein what is described for this may apply by analogy to the (k+1)-th cycle (if present) and/or the (k−1)th cycle (if present). The k-th cycle may be arranged to form the k-th layer of the layer stack from the k-th layer forming material (e.g., niobium oxide), for example, by the k-th coating material source 106a of the coating apparatus. The k-th coating material source 106a is adapted to provide the k-th layer forming material (e.g., niobium oxide) at the transport path and/or in a coating region through which the substrate is moved along the transport path (e.g., by a reciprocating motion or rotational motion of the substrate carrier). For example, the k-th layer forming material may be different from the (k+1)-th layer forming material (e.g., silicon oxide), if present, and/or the (k−1)th layer forming material (e.g., silicon oxide), if present, and/or coincide with the (k+z)-th layer forming material (2=z or 3=z).

In the two-sided coating phase 611 of the kth cycle, the front side process 601 and the back side process 603 may be carried out (operating state=ON), for example, simultaneously and/or for the same duration, by which the kth layer forming material is provided.

In the final phase 613 of the kth cycle, which, for example, is adjacent to the two-sided coating phase 611 and/or the subsequent (k+1)th cycle, the front side process 601 may be interrupted with a time delay before the back side process 603 (operating state=OFF). This ends the formation of the kth layer of the front-side coating before the formation of the kth layer of the back-side coating. For example, the front side process 601 may be interrupted by a time interval t₂(also referred to as termination time difference) before the back side process 603 is interrupted. The completion time difference t₂may be, for example, the duration of the completion phase 613.

In the start phase 615 of the kth cycle, e.g., adjacent to the two-sided coating phase 611 and/or the previous (k−1)th cycle, the backside process 603 may be started (e.g., continued) with a time delay after the front side process 601 (operating state=ON). For example, the start (e.g., the continuation) of the backside process 603 may occur before the start (e.g., the continuation) of the front side process 601 by a time interval Δt (also referred to as the reference time difference). The reference time difference Δt may, for example, be the duration of the start phase 615.

For example, several consecutively performed cycles may match in the reference time difference Δt. Alternatively or additionally, several consecutively performed cycles may differ from one another in the layer formation material and/or the duration of the first phase 611.

Diagram 600b shows the layer thickness as a function of time t, for the exemplary case that the layer formation rate r1 of the front side process 601 is equal to the layer formation rate r2 of the back side process 603, which does not necessarily have to be the case. As shown, the actual layer thickness of the layer formed by the front-side process 601 increases as a function of the time t and the layer formation rate until it reaches the target layer thickness dl at the end of the two-sided coating phase 611. This occurs for the back-side process 603 at the end of the final phase 613.

If the front-side process 601 and the back-side process 603 provide the same layer formation rate (also referred to as coating rate), the completion time difference t₂can be equal to the reference time difference Δt, but does not necessarily have to be (then also referred to as layer formation difference). If the layer formation rate r1 of the front-side process 601 is greater than the layer formation rate r2 of the back-side process 603, the finishing time difference t₂can be greater than the reference time difference Δt.

The difference in completion time can, for example, be based on the actual state of the coating result determined in 101, for example, a comparison of this with a corresponding target state. For example, the determination 101 of the actual state of the coating result may reveal that the backside process 603 has progressed further than it should and is therefore interrupted at the same time as the front side process 601 (t_{U}=0). For example, determination 101 of the actual state of the coating result may reveal that the layer thickness of the layer formed by the front-side process 601 is less than it should be and is therefore interrupted at the same time as the back-side process 603.

In an exemplary implementation 1, the reference time difference Δt is used as a process difference that may be, for example, greater than 1% (or than 5% or than 10%) of the duration of the two-sided coating phase and/or in a range of about more than 1 second(s) and/or less than about 20 s, e.g., in a range of about 5 s to about up to 10 s. Alternatively or additionally, the reference time difference Δt may be greater than the duration required for several (e.g., more than 10 or more than 50 or more than 100) revolutions of the substrate carrier.

In an exemplary implementation 2, for example, configured according to implementation 1, the completion time difference is used as a process difference, which may, for example, be greater than 1% (or than 5% or than 10%) of the duration of the two-sided coating phase and/or in a range of about more than 1 second(s) and/or less than about 20 s, for example, in a range of about 5 s to about up to 10 s.

In an exemplary implementation 3, for example, configured according to implementation 1 or 2, the layer formation difference is used as a process difference, which may have, for example, that the layer formation rate r1 of the front side process 601 and the layer formation rate r2 of the back side process 603 differ by more than 1% (or as 5% or as 10%).

More generally, the process difference may provide a difference 620 (also referred to as a coating thickness difference) between the actual coating thickness of the coating formed by the front side process 601 and the actual coating thickness of the coating formed by the back side process 603. The layer thickness difference 620 may be present, for example, for each cycle and/or at least in (e.g., at the end of) the two-sided coating phase 611. The coating thickness difference 620 is generally a function of the coating formation difference and the reference time difference Δt.

The greater the difference in coating thickness and/or the earlier the difference in coating thickness in the start phase 615 fulfills a criterion (e.g., exceeds a threshold value), the better the actual states of the front side coating and the back side coating may be distinguished from one another using the model.

For example, the difference in coating thickness (at least in the start phase 615) may be greater than 2.5 nm, 5 nm or 10 nm and/or fulfill the criterion if, for example, the variance of the determined coating rate is <5%, <2% or <1%.

In an exemplary implementation, the following takes place (e.g., several times per cycle or at least per first phase): Determining the time-dependent actual state of the coating result by the model based on the actual state of the spectral response of the coating result, comparing the actual state of the coating result with a (e.g., time-independent) target state of the coating result, and controlling the coating process based on the result of the comparison.

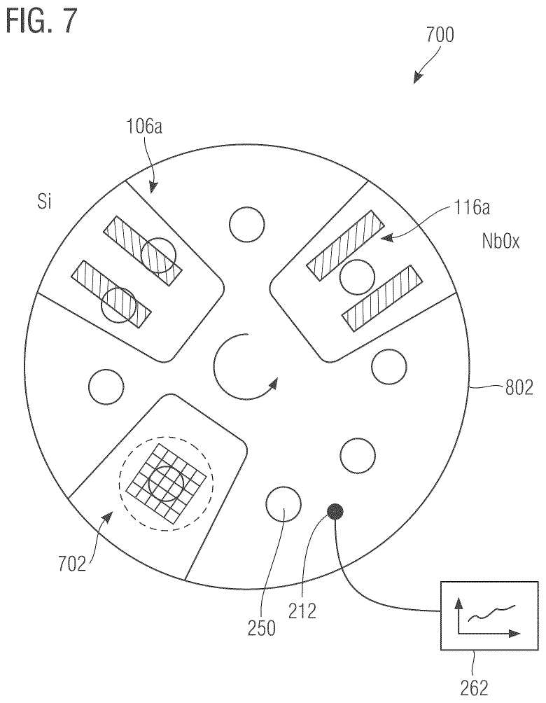

FIG. 7 illustrates a vacuum arrangement 104 according to various embodiments 700 in a schematic top view or cross-sectional view, in which the vacuum arrangement 104 further comprises a reaction device 702 (e.g., ion source) which is arranged to oxidize the coating material emitted from the coating material sources 106a, 116a to the layer forming material. The components 106a, 116a, 702 shown here arranged above the transport path 111 may additionally be arranged below the transport path 111 in analogy of the same type.

Above and below the transport path 111, a coating material source 106a, 106b configured as a silica oxide source is arranged, which is provided by a Si target (e.g., as part of a sputtering device) and the reaction device 702. Above and below the transport path 111 there is further arranged a coating material source 116a, 116b configured as a niobium oxide source, which is provided by an NbOxtarget (e.g., as part of a sputtering device) and the reaction device 702.

It may further be understood that the model may be based on one or more than one of the following information: a sensored emission rate of the front side process and/or the back side process; a sensored layer formation rate of the front side process and/or the back side process, an operating point (e.g., operating condition) of the front side process and/or the back side process.

In general, the emission rate and the layer formation rate may be linked to each other, for example, via a system-specific and/or material-specific factor that may be determined in advance. In rare cases, the emission rate and the layer formation rate may be identical, for example, if the emission rate is measured at the location of the transport path.

For example, the determination of an actual state of the coating result (e.g., by the model) may be based on an indication of which sub-process of the coating process is interrupted. Then, for example, the layer stack formed by this sub-process may be set as invariant, for example, according to the actual state that was determined at the time when the sub-process was interrupted. More generally speaking, the model parameters of a layer stack may be set as variant if coating material is also added to it.

It may be understood that, alternatively or in addition to the operating condition explained above, any other operating parameter may be changed according to a specification to implement the process difference. For example, the rate at which the layer forming material is emitted (also referred to as emission rate) may be changed as an operating parameter according to the specification. For example, a shutter by which the layer forming material is blocked (also referred to as the emission rate) may be shifted as a working parameter according to the specification.

In an exemplary implementation, the stratification difference (e.g., sensory) is determined and the model is initialized based on the process difference that has the reference time difference and the stratification difference. For example, the actual result determined by the model is based on the stratification rate of each sub-process and the reference time difference.

In an exemplary working example, the coating of the front and rear sides is started with a slight time delay of approximately 5 s to 10 s, for example, with either the front or rear side first. The coating parameters are selected as follows:
The coating rate on the side on which the coating is started first is set to be greater than or equal to the coating rate on the other side.
The time offset (reference time difference) is set in such a way that the layer thickness of the front layer is greater than that of the back layer as long as it is sputtered.
During the coating process, optical spectra are continuously recorded with a broadband spectrometer and provided with the time stamp of the recording. The current coating thicknesses (also referred to as actual coating thicknesses) at the time of recording are fitted from the recorded spectra using a model. The following applies:
   For the first fits (also referred to as equalization calculation), the thickness resulting from the projected coating rate and time is used as the starting point for the fits. The current coating rate (also known as the actual coating rate) is then calculated from the fitted thicknesses. This serves as the basis for further calculations and for determining the switch-off time.
   As long as the coating is running on both sides, the two coating thicknesses are fitted simultaneously. The ranges for the possible coating thicknesses are limited during the fit. The maximum permissible thickness of the coating thickness on the rear side is set as less than the minimum permissible coating thickness of the coating thickness on the front side.
   If the coating only runs on one side, only this side is fitted. The last value determined is used for the coating thickness on the other side.

This means that double-sided coating with control by an optical monitoring system is possible almost simultaneously, even if the coating systems on the front and back are the same. Even if the coating components for the front and back are arranged completely symmetrically, only one sensor is required for a broadband spectrum. As a result, the throughput of the system may be increased. Simultaneous sputtering on a substrate also reduces the bending of the substrate, as the same layer tension is generated on the front and back.

In the following, various examples are described which relate to the above described and illustrated in the figures.

Example 1 is a (e.g., computer-implemented) method, comprising: determining an actual state of a result (also referred to as an actual result) of a two-sided coating process by which a first layer stack is formed on a front side of a substrate and a second layer stack is formed on a back side of the substrate, based on: a model implementing a correlation (e.g., mapping) between the result (e.g., a state thereof) and a spectral response (e.g., a state thereof) of the result, and an actual state of the spectral response (also referred to as an actual spectral response), an indication of a difference between a first sub-process of the coating process by which a second layer stack is formed on a front side of the substrate and a second layer stack is formed on a back side of the substrate, based on a state thereof) of the result, and an actual state of the spectral response (also referred to as an actual spectral response), an indication of a difference between a first sub-process of the coating process by which the first layer stack is formed and a concurrent second sub-process of the coating process by which the second layer stack is formed, driving the coating process, and based on the actual state of the result.

Example 2 is the method according to example 1, wherein the coating process is controlled according to a specification, which preferably represents a target state of the result (also referred to as target result), for example, wherein the control of the coating process is based on a comparison of the specification with the actual state of the result (e.g., on a result of the comparison).

Example 3 is the process according to example 2, wherein the first layer stack and the second layer stack have a common structure according to the target state.

Example 4 is the method according to example 2 or 3, wherein the first layer stack and the second layer stack according to the target state match in one or more than one of the following: a spatial sequence of layers of different chemical composition; a chemical composition of one or more than one layer; a number of layers of different chemical composition; a total thickness; a spectral response.

Example 5 is the method according to any one of examples 1 to 4, further comprising: driving a measuring member to sense the actual state of the spectral response.

Example 6 is the method according to any one of examples 1 to 5, wherein the difference between a first sub-process and the second sub-process causes a difference between the first layer stack and the second layer stack in terms of: a rate (e.g., layer formation rate) at which the layer thickness thereof changes; and/or a time at which the layer thickness thereof reaches a target state (also referred to as target layer thickness).

Example 7 is the method according to any one of Examples 1 to 6, wherein the difference between a first sub-process and the second sub-process comprises: a difference in the timing at which an operating point (e.g., an operating state) is changed according to a predetermination; and/or a difference in a rate (emission rate) at which a coating material is provided (e.g., emitted, e.g., toward the substrate) therefrom.

Example 8 is the method according to any one of examples 1 to 7, wherein the controlling comprises starting, interrupting, continuing and/or terminating the first sub-process and the second sub-process with a time offset to each other; wherein the time offset is preferably based on the actual state of the result and/or, wherein the difference between a first sub-process is preferably based on or comprises the time offset.

Example 9 is the method according to any one of examples 1 to 8, wherein the controlling comprises controlling one or more than one manipulation member arranged to influence the coating process in response to being controlled, of which for example, a first manipulation member is arranged to influence the first sub-process in response to being controlled and/or of which for example, a second manipulation member is arranged to influence the second sub-process in response to being controlled.

Example 10 is the method according to any one of examples 1 to 9, wherein determining the actual state of the result comprises setting the model at least partially invariant with respect to the first layer stack when the first coating process is interrupted; and/or with respect to the second layer stack when the second coating process is interrupted.

Example 11 is the method according to any one of examples 1 to 10, wherein the spectral response comprises a transmission spectrum; and/or wherein the spectral response is determined by ellipsometry.

Example 12 is the method according to any one of examples 1 to 11, wherein the model is initialized based on the specification.

Example 13 is the method according to any one of examples 1 to 12, wherein the first layer stack and the second layer stack each comprise or at least comprise one or more than one dielectric and/or optically transmissive (e.g., transparent or translucent) material (also referred to as layer forming material).

Example 14 is the method according to any one of examples 1 to 13, wherein the first layer stack and the second layer stack each comprise or at least comprise one or more than one ceramic.

Example 15 is the method according to any one of examples 1 to 14, wherein the controlling of the coating process is performed according to a cycle comprising: a first phase in which the second sub-process is started (e.g., continued) with a time delay after the first sub-process; a second phase in which the first sub-process and the second sub-process are performed simultaneously, preferably concurrently in a coating material provided by means thereof; a third phase in which the first sub-process is started (e.g., a second phase in which the first sub-process and the second sub-process are carried out simultaneously, preferably concurrently in a coating material provided by means thereof; a third phase in which the first sub-process is interrupted (e.g., terminated) with a time delay before the second sub-process, wherein the cycle comprises changing the coating material provided by the first sub-process and the second sub-process.

Example 16 is a computer program (computer program product) comprising instructions stored on a computer readable medium which, when executed by a processor, is arranged to cause the processor to perform the method according to any one of examples 1 to 15.

Example 17 is a computer readable medium storing instructions arranged, when executed by a processor, to cause the processor to perform the method according to any one of examples 1 to 15.

Example 18 is a control device comprising one or more than one processor arranged to perform the method according to any one of examples 1 to 15.

Example 15 is a processing arrangement, comprising: the control device according to example 14; at least one (i.e., one or more than one) first coating material source arranged to perform the first sub-process; at least one (i.e., at least one (i.e., one or more than one) second coating material source adapted to perform the second sub-process; wherein the control device is adapted to drive the at least one first coating material source and the at least one second coating material source (for driving the coating process) based on the actual state of the result; optionally further comprising a transport device for transporting the substrate along a transport path arranged between the at least one first coating material source and the at least one second coating material source; and/or a vacuum chamber in which the transport path is arranged.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. A method, comprising:
determining an actual state of a result of a two-sided coating process, by which a first layer stack is formed on a front side of a substrate and a second layer stack is formed on a back side of the substrate, based on:
a model that implements a correlation between the result and a spectral response of the result; and,
an actual state of the spectral response;
information about a difference between a first sub-process of the coating process, by which the first layer stack is formed; and,
a simultaneous second sub-process of the coating process, by which the second layer stack is formed, controlling the coating process based on the actual state of the result.

14. The method according to claim 13, wherein said controlling of the coating process is based on a preset representing a target state of the result.

15. The method according to claim 14, wherein said controlling of the coating process is based on a comparison between the preset and the actual state of the result.

16. The method according to claim 14, wherein, according to the preset, the first layer stack and the second layer stack have a common architecture.

17. The method according to claim 14, wherein the difference between said first sub-process and said second sub-process comprises a difference in a point of time, at which a working parameter is changed based on the preset.

18. The method according to claim 13, wherein the difference between said first sub-process and said second sub-process causes a difference between the first layer stack and the second layer stack in a rate, with which a layer thickness the first layer stack and the second layer stack changes.

19. The method according to claim 13, wherein said controlling the coating process comprises starting, interrupting, continuing or terminating the first sub-process and the second sub-process with a time offset relative to one another as difference.

20. The method according to claim 19, wherein the time offset is based on the actual state of the result.

21. The method according to claim 13, wherein the spectral response comprises a transmission spectrum or reflection spectrum.

22. The method according to claim 13, wherein said controlling the coating process is performed according to a sequence, which comprises:
a first phase in which the second sub-process is started with a time delay to the first sub-process;
a second phase in which the first sub-process and the second sub-process are carried out simultaneously; and,
a third phase in which the first sub-process is interrupted with a time delay to the second sub-process.

23. The method according to claim 13, wherein the first sub-process and the second sub-process provide a common coating material.

24. The method according to claim 13, wherein the difference between said first sub-process and said second sub-process comprises a difference in the rate at which coating material is provided.

25. The method according to claim 13, wherein the difference between said first sub-process and said second sub-process causes a difference between the first layer stack and the second layer stack with respect to a point in time at which the layer thickness reaches a target state.

26. The method according to claim 14, wherein, according to the preset, the first layer stack and the second layer stack have a common spatial sequence of layers, including at least two layers differing from each other in a chemical composition thereof.

27. The method according to claim 14, wherein, according to the preset, the first layer stack and the second layer stack have a common chemical composition of one or more than one layer thereof.

28. The method according to claim 14, wherein, according to the preset, the first layer stack and the second layer stack have a common number of layers, which differ from each other in a chemical composition thereof.

29. The method according to claim 14, wherein, according to the preset, the first layer stack and the second layer stack have a common total thickness.

30. The method according to claim 14, wherein, according to the preset, the first layer stack and the second layer stack have a common spectral response.

31. A non-volatile computer readable medium storing instructions configured, when executed by a processor, to cause the processor to perform the following:
determining an actual state of a result of a two-sided coating process by which a first layer stack is formed on a front side of a substrate and a second layer stack is formed on a back side of the substrate, based on:
a model that implements a correlation between the result and a spectral response of the result; and,
an actual state of the spectral response; and,
information about a difference between a first sub-process of the coating process, by which the first layer stack is formed, and a simultaneous second sub-process of the coating process, by which the second layer stack is formed, controlling the coating process based on the actual state of the result.

32. A control device comprising one or more than one processor adapted to perform the following:
determining an actual state of a result of a two-sided coating process by which a first layer stack is formed on a front side of a substrate and a second layer stack is formed on a back side of the substrate, based on:
a model that implements a correlation between the result and a spectral response of the result; and,
an actual state of the spectral response; and,
information about a difference between a first sub-process of the coating process, by which the first layer stack is formed, and a simultaneous second sub-process of the coating process, by which the second layer stack is formed, controlling the coating process based on the actual state of the result.
